(19) United States
(12) Patent Application Publication
(10) Pub. No.: US 2025/0109015 A1
(43) Pub. Date: Apr. 3, 2025

(54) MICROELECTROMECHANICAL COMPONENT WITH GAP-CONTROL STRUCTURE AND A METHOD FOR MANUFACTURING IT

(71) Applicant: Murata Manufacturing Co., Ltd., Nagaokakyo-shi (JP)

(72) Inventors: Jeanette LINDROOS, Helsinki (FI); Masakazu FUKUMITSU, Nagaokakyo-shi (JP)

(21) Appl. No.: 18/894,715

(22) Filed: Sep. 24, 2024

(30) Foreign Application Priority Data
Sep. 28, 2023 (EP) 23200481.2

(51) Int. Cl. B81C 1/00; B81B 7/00

(52) U.S. Cl. CPC B81C 1/00269; B81B 7/0077; B81B 2203/0307; B81B 2203/0315; B81B 2207/07; B81B 2207/095; B81C 2201/013; B81C 2201/0174; B81C 2203/0109; B81C 2203/035

(57) ABSTRACT

A device includes a cap wafer with a sealing region surrounding a gap-control region, and a structure wafer with a corresponding sealing region and gap-control region. The cap wafer has top and bottom surfaces, defining an xy-plane, and a vertical z-direction perpendicular to this plane. The structure wafer is similarly oriented, with its top surface parallel to the xy-plane. The cap wafer and structure wafer are bonded by a eutectic seal connecting their sealing regions, ensuring alignment of their gap-control regions along the z-axis. The device also includes a metal layer located on the bottom surface of the cap wafer in its gap-control region, and the structure wafer features a standoff protruding from its top surface within its gap-control region, extending along the z-direction to contact the metal layer.

### CROSS REFERENCE TO RELATED APPLICATION

This application claims priority to European Patent Application No. 23200481.2, filed Sep. 28, 2023, the contents of which is hereby incorporated by reference in its entirety.

### TECHNICAL FIELD

This disclosure is directed to electronic devices and more particularly to Microelectromechanical components. The present disclosure further concerns eutectic bonding of microelectromechanical components with a gap-control structure.

### BACKGROUND

Microelectromechanical systems (MEMS) are the technology of microscopic devices which combine mechanical and electrical features. MEMS devices, also called MEMS elements, can have either simple or complex structures with various moving parts. They include devices such as gyroscopes, acceleration sensors, magnetometers, and pressure sensors. MEMS devices may be fabricated from a silicon wafer by microfabrication techniques.

Electronic chips, also called dies, are prepared by manufacturing various electronic structures on a substrate and cutting the substrate into small, chip-size pieces. These chips may be MEMS devices. Several MEMS elements may be built on the same die. This allows significant cost and area reduction. Once the MEMS elements are built, they may need to be sealed in a particular environment depending on their function.

Eutectic bonding, also known as eutectic soldering, is a well-established semiconductor bonding technology that involves bonding wafers together by high pressure using a seal formed of two or more metal films which transform into a eutectic alloy at a specific temperature (eutectic temperature). Due to their easy preparation techniques and good wettability, eutectic alloys form excellent seals in electronic devices. Eutectic bonding is widely used in MEMS technology for the hermetic sealing of MEMS components. During the bonding process, at the eutectic temperature, the eutectic alloy is in a liquid phase. Because bonding process involves pressing wafers together at high pressure, in some circumstances, it may be challenging to accurately control the gap height between the bonded wafers, and thus the MEMS element cavity height, due to the softness of the liquid eutectic alloy.

### SUMMARY OF THE INVENTION

An object of the present disclosure is to provide a solution to the problem described above. The disclosed solution allows MEMS vertical gap height control in bonded microelectromechanical components, especially eutectic bonding. Exemplary aspects provided in this disclosure describe ways to implement the solution. The improvement is achieved by features of the microelectromechanical component and a manufacturing method.

In some aspects, the techniques described herein relate to a microelectromechanical component including: a cap wafer including a cap wafer sealing region and a cap wafer gap-control region, the cap wafer sealing region surrounds the cap wafer gap-control region; and a structure wafer including a structure wafer sealing region and a structure wafer gap-control region, the structure wafer sealing region surrounds the structure wafer gap-control region; wherein the cap wafer has a top surface and a bottom surface, the top surface of the cap wafer defines a horizontal xy-plane and a vertical z-direction which is perpendicular to the xy-plane, wherein the structure wafer has a top surface and a bottom surface, and the top surface of the structure wafer is parallel to the xy-plane, and wherein the cap wafer and the structure wafer are bonded to each other by a eutectic seal which connects the cap wafer sealing region to the structure wafer sealing region so that the cap wafer gap-control region is aligned with the structure wafer gap-control region along a z-axis, the microelectromechanical component further includes a metal layer, wherein the metal layer is located at the bottom surface of the cap wafer in the cap wafer gap-control region, and the structure wafer further includes a standoff in the structure wafer gap-control region, wherein the standoff protrudes outward from the top surface of the structure wafer and extends along the z-direction so that it meets the metal layer.

In some aspects, the techniques described herein relate to a method for manufacturing a microelectromechanical component with a gap-control structure, the method includes steps: forming a first metal layer on a bottom surface of a cap wafer in a cap wafer gap-control region, forming a second metal layer on the bottom surface of the cap wafer next to the first metal layer in the cap wafer gap-control region, forming a standoff in the structure wafer gap-control region so that the standoff protrudes outward from a top surface of the structure wafer and extends in a z-direction, forming a third metal layer on the top surface of the structure wafer next to the standoff in the structure wafer gap-control region, placing the cap wafer on top of the structure wafer so that the first metal layer is aligned with the standoff along a z-axis and the second metal layer is aligned with the third metal layer along the z-axis, and bonding a cap wafer sealing region and the structure wafer sealing region together so that the top surface of the standoff is connected to the first metal layer, and the second metal layer and the third metal layer form a eutectic anchor,

The disclosure is based on the idea of including a structure comprising a standoff and an adjacent eutectic anchor inside the MEMS element. The standoff provides an accurate control of the MEMS gap height during the eutectic bonding of the component whereas the anchor improves the mechanical anchoring of the standoff. The structure provides new improvements of gap control and robustness of the eutectic bond in the microelectromechanical component.

### BRIEF DESCRIPTION OF THE DRAWINGS

In the descriptions that follow, like parts are marked throughout the specification and drawings with the same numerals, respectively. The drawings are not necessarily drawn to scale and certain drawings may be illustrated in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 illustrates a bottom view of a cap wafer and a top view of a structure wafer comprising a gap-control region and a sealing region in accordance with aspects of the present disclosure;

FIG. 2a illustrates a simplified example of a bottom view of a cap wafer and a top view of a structure wafer in a microelectromechanical component in accordance with aspects of the present disclosure;

FIG. 2b illustrates a sectional view of the microelectromechanical component comprising the cap wafer and the structure wafer shown in FIG. 2a in accordance with aspects of the present disclosure;

FIG. 2c illustrates another simplified example of a bottom view of a cap wafer and a top view of a structure wafer in a microelectromechanical component in accordance with aspects of the present disclosure;

FIG. 2d illustrates a sectional view of the microelectromechanical component comprising the cap wafer and the structure wafer shown in FIG. 2c in accordance with aspects of the present disclosure;

FIGS. 3a, 3b and 3c illustrate different possible shapes and positions of eutectic anchors in a microelectromechanical component in accordance with aspects of the present disclosure;

FIGS. 4a and 4b illustrate simplified examples of sectional views of microelectromechanical components comprising a gap-control structure in accordance with aspects of the present disclosure;

FIGS. 5a, 5b, 5c, 5d, 5e and 5f provide a simplified illustration of an example method for manufacturing a microelectromechanical component with a gap-control structure in accordance with aspects of the present disclosure;

FIGS. 6a and 6b illustrate a simplified example of a sectional view of a microelectromechanical component comprising a gap-control structure before and after bonding in accordance with aspects of the present disclosure;

FIGS. 7a and 7b illustrate another simplified example of a sectional view of a microelectromechanical component comprising a gap-control structure wherein the eutectic anchor comprises a metalloid layer in accordance with aspects of the present disclosure; and

FIGS. 8a and 8b illustrate a further simplified example of a sectional view of a microelectromechanical component comprising a gap-control structure before and after bonding in accordance with aspects of the present disclosure.

### DETAILED DESCRIPTION OF THE DISCLOSURE

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

The disclosure describes a microelectromechanical component comprising a cap wafer and a structure wafer. The cap wafer has a top surface and a bottom surface. The top surface of the cap wafer defines a horizontal xy-plane and a vertical z-direction which is perpendicular to the xy-plane. The cap wafer comprises a cap wafer sealing region and a cap wafer gap-control region, and the cap wafer sealing region surrounds the cap wafer gap-control region. The structure wafer has a top surface and a bottom surface, and the top surface of the structure wafer is parallel to the xy-plane. The structure wafer comprises a structure wafer sealing region and a structure wafer gap-control region, and the structure wafer sealing region surrounds the structure wafer gap-control region. The cap wafer and the structure wafer are bonded to each other by a eutectic seal which connects the cap wafer sealing region to the structure wafer sealing region so that the cap wafer gap-control region is aligned with the structure wafer gap-control region along the z-axis. The microelectromechanical component further comprises a metal layer. The metal layer is located at the bottom surface of the cap wafer in the cap wafer gap-control region. The structure wafer further comprises a standoff in the structure wafer gap-control region. The standoff protrudes outward from the top surface of the structure wafer and extends along the z-direction so that it meets the metal layer. The microelectromechanical component further comprises at least one eutectic anchor attached to the top surface of the structure wafer in the structure wafer gap-control region next to the standoff. The eutectic anchor extends along the z-direction from the top surface of the structure wafer to the bottom surface of the cap wafer.

Any direction or plane which is parallel to the xy-plane defined by the cap wafer can be called horizontal. The direction which is perpendicular to the xy-plane can be called vertical direction. Expressions such as “top”, “bottom”, “above”, “below”, “up” and “down” refer in this disclosure to differences in the vertical z-coordinate. These expressions do not imply anything about how the device should be oriented with respect to the earth's gravitational field when the component is in use or when it is being manufactured.

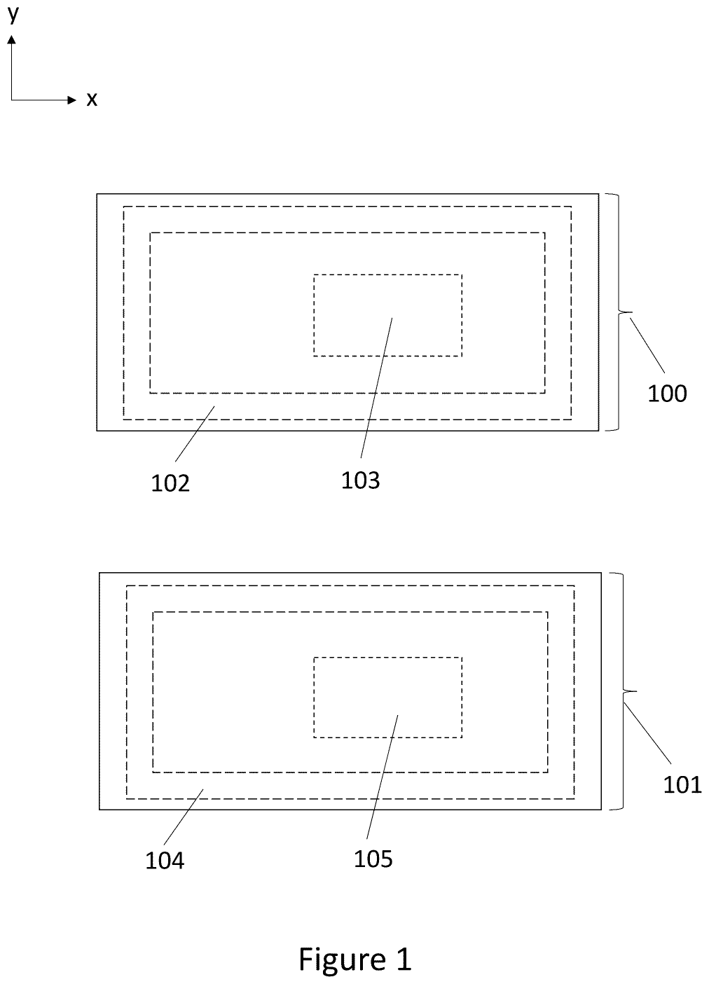

FIG. 1 illustrates an example of a bottom view of a cap wafer and a top view of a structure wafer. The cap wafer 100 comprises a cap wafer gap-control region 103 and a cap wafer sealing region 102. In this example, the cap wafer sealing region 102 is adjacent to the edges of the cap wafer. The cap wafer sealing region 102 surrounds the cap wafer gap-control region 103. Similarly, the structure wafer 101 comprises a structure wafer gap-control region 105 and a structure wafer sealing region 104. In this example, the structure wafer sealing region 104 is adjacent to the edges of the structure wafer. The structure wafer sealing region 104 surrounds the structure wafer gap-control region 105. The cap wafer 100 and the structure wafer 101 may be bonded to each other so that a eutectic seal connects the cap wafer sealing region 102 to the structure wafer sealing region 104 and the cap wafer gap-control region 103 is aligned with the structure wafer gap-control region 105 along the z-axis.

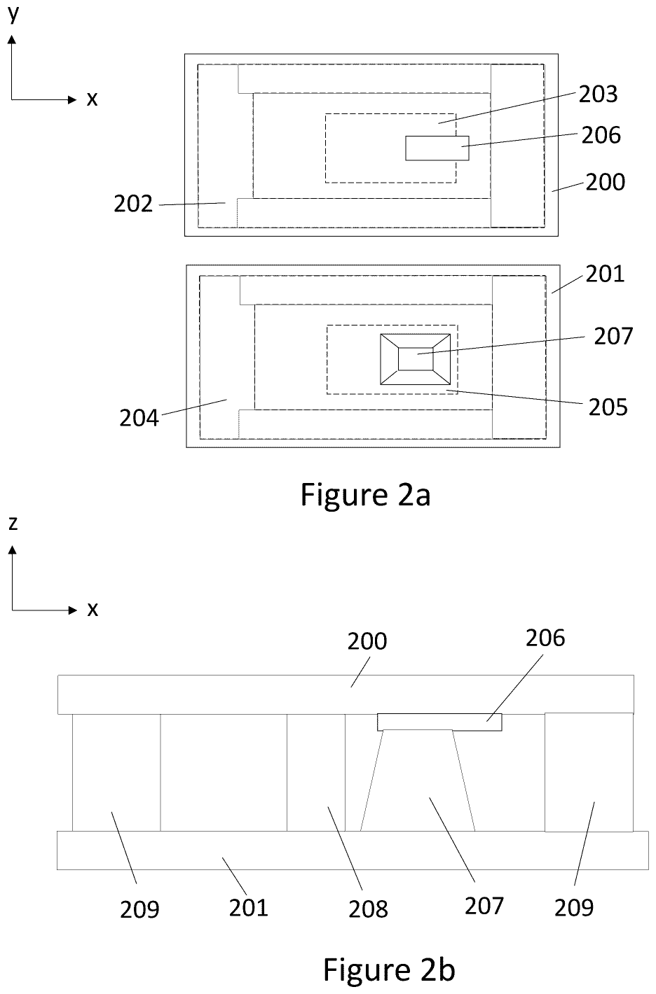

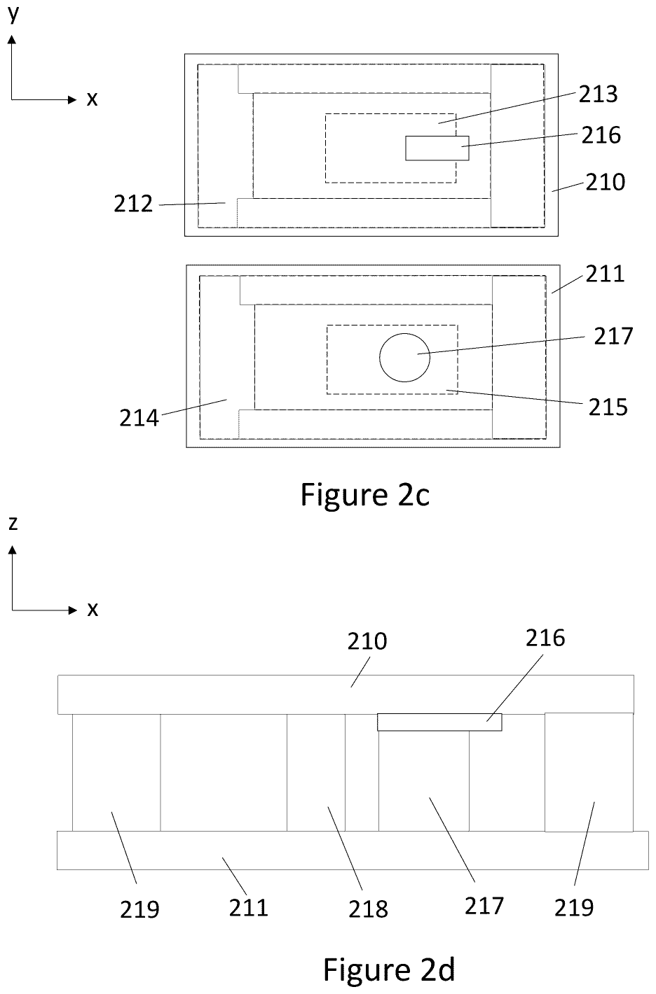

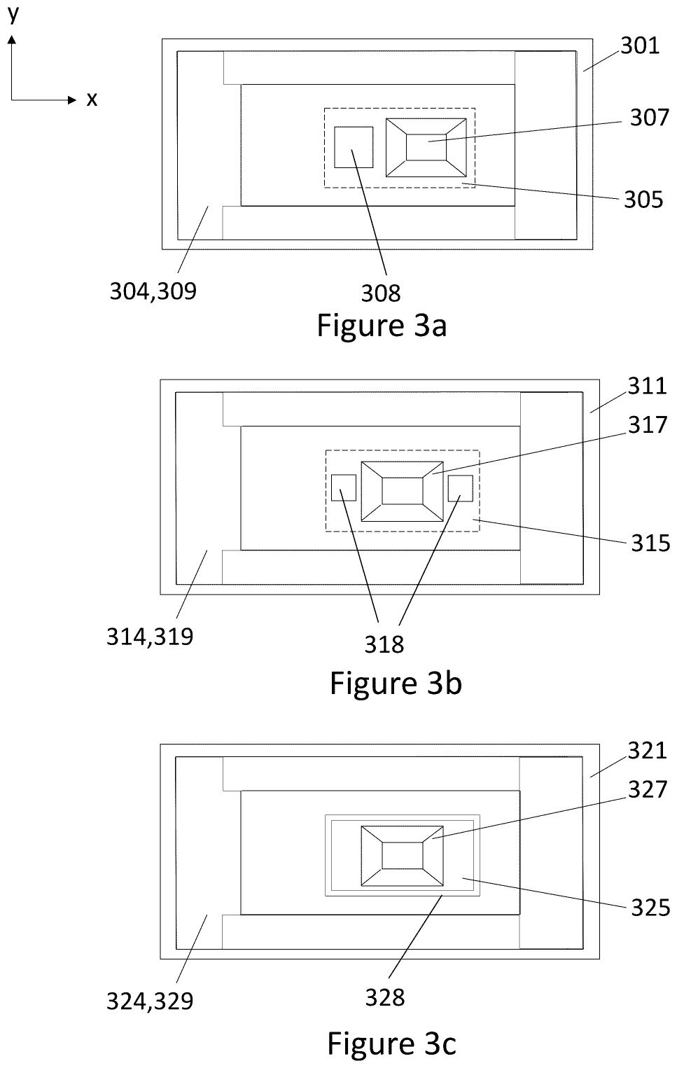

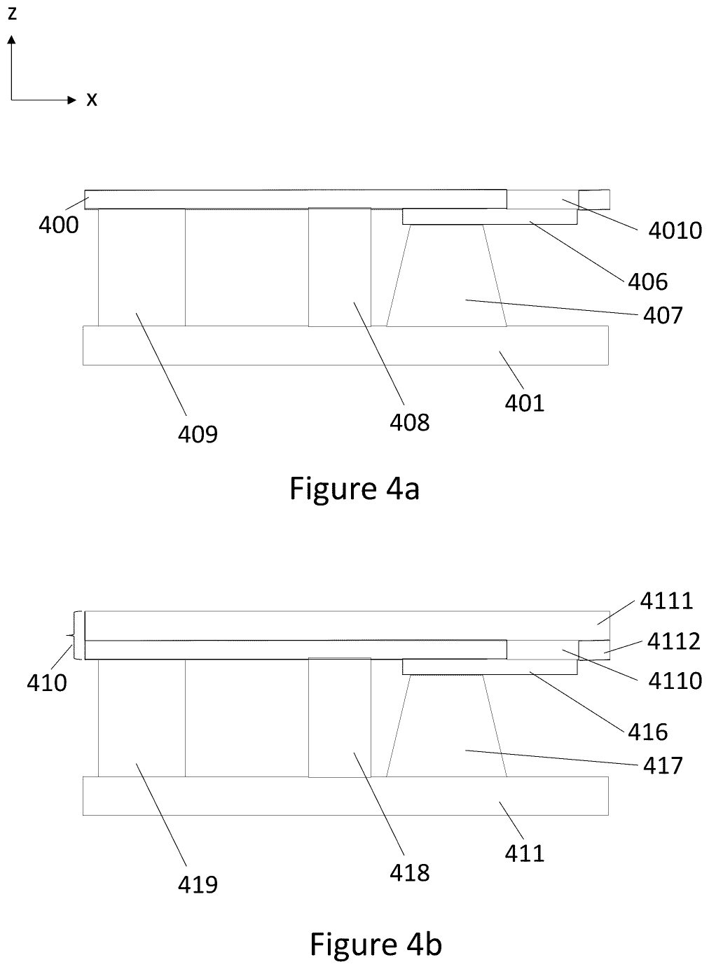

FIG. 2a illustrates a simplified example of a bottom view of a cap wafer and a top view of a structure wafer in a microelectromechanical component. In this example, the cap wafer 200 comprises a cap wafer sealing region 202 which is adjacent to the edges of the cap wafer 200. The cap wafer 200 further comprises a cap wafer gap-control region 203. The cap wafer sealing region 202 surrounds the cap wafer gap-control region 203. A metal layer 206 is attached to the bottom surface of the cap wafer 200 in the cap wafer gap-control region 203. In this example, the metal layer 206 extends outside the cap wafer gap-control region. Alternatively, the metal layer may be located within the cap-wafer gap control region 203. These options may apply to any aspect in this disclosure. The structure wafer 201 comprises a structure wafer sealing region 204. In this example, the structure wafer sealing region 204 is adjacent to the edges of the structure wafer 201. The structure wafer 201 further comprises a structure wafer gap-control region 205. The structure wafer sealing region 204 surrounds the structure wafer gap-control region 205. The structure wafer 201 further comprises a standoff 207 located in the structure wafer gap-control region 205. The standoff 207 protrudes in the z-direction outward from the top surface of the structure wafer 201. The microelectromechanical component may comprise a plurality of standoffs. The standoff shape may for example be a truncated pyramid shape, or a pillar-like shape. The pillar like-shape may be, but is not limited to, a cylinder, a hexagonal prism, or a cuboid. These options may apply to any aspect in this disclosure. In this example, the standoff 207 has a truncated pyramid shape.

FIG. 2b illustrates a sectional view of the microelectromechanical component comprising the cap wafer and structure wafer shown in FIG. 2a. The cap wafer 200 and the structure wafer 201 are bonded to each other by a eutectic seal 209 which connects the cap wafer sealing region to the structure wafer sealing region so that the cap wafer gap-control region is aligned with the structure wafer gap-control region along the z-axis. The standoff 207, which has a truncated pyramid shape, protrudes outward from the top surface of the structure wafer 201 and extends along the z-direction so that it meets the metal layer 206. The microelectromechanical component further comprises a eutectic anchor 208 which is attached to the top surface of the structure wafer 201 in the structure wafer gap-control region next to the standoff. The eutectic anchor 208 extends along the z-direction from the top surface of the structure wafer 201 to the bottom surface of the cap wafer 200. The distance, in any direction parallel to the xy-plane, between the eutectic anchor and the standoff may be less than the distance between the eutectic seal and the standoff. The distance, in any direction parallel to the xy-plane, between the eutectic anchor and the standoff may be in the range [5-100] μm, or [10-50] μm, or [20-80] μm, or [50-60] μm. The standoff 207 and the eutectic anchor 208 form a gap-control structure.

The metal layer 206 may be made of a variety of metals that include but are not limited to Al, Cu, Ag, Au, Pt, Pd, Mo or metal alloys. The metal layer may be formed by a variety of deposition methods such as sputtering, chemical vapor deposition, molecular beam epitaxy, electron beam physical vapor evaporation, or laser metal deposition. The thickness of the metal layer 206 may be in the range [0.1-1.0] μm, or [0.1-0.5] μm, or [0.3-0.7] μm. The eutectic anchor may be made of a eutectic alloy formed by two or more metals which include, but are not limited to, Au—Sn, Au—In or Cu—Sn. These metals may be formed by a variety of deposition methods such as sputtering, chemical vapor deposition, molecular beam epitaxy, electron beam physical vapor evaporation, or laser metal deposition. Alternatively, the eutectic anchor may be made of an alloy comprising a metalloid. For example, the eutectic anchor may be made of Ge, Al and Ti, or it may be made of Ge and Al. The eutectic anchor and eutectic seal may be made of the same eutectic alloy. Alternatively, the eutectic anchor and the eutectic seal may be made of different eutectic alloys. These options may apply to any aspect in this disclosure.

The structure wafer may be a semiconductor device layer which has been attached to a support layer (not illustrated). The device layer may be a layer of silicon. The device layer and the support layer may for example be parts of a silicon-on-insulator (SOI) substrate where MEMS elements can be formed by patterning the top silicon layer (the device layer). The cap wafer may be an insulating wafer such as a glass layer, or a wafer comprising semiconducting parts and insulating parts, or a wafer comprising metal parts and insulating parts. These options may apply to any aspect in this disclosure.

FIG. 2c illustrates another simplified example of a bottom view of a cap wafer and a top view of a structure wafer in a microelectromechanical component. In this example, the standoff 217 has a pillar-like shape. Reference numbers 210, 211, 212, 213, 214, 215 and 216 in FIG. 2c correspond to reference numbers 200, 201, 202, 203, 204, 205 and 206, respectively, in FIG. 2a.

FIG. 2d illustrates a sectional view of the microelectromechanical component comprising the cap wafer and structure wafer shown in FIG. 2c. The cap wafer 210 and the structure wafer 211 are bonded to each other by a eutectic seal 219 which connects the cap wafer sealing region to the structure wafer sealing region so that the cap wafer gap-control region is aligned with the structure wafer gap-control region along the z-axis. The standoff 217 has a cylinder shape. The microelectromechanical component further comprises a eutectic anchor 218 which is attached to the top surface of the structure wafer 211 in the structure wafer gap-control region next to the standoff. The eutectic anchor 218 extends along the z-direction from the top surface of the structure wafer 211 to the bottom surface of the cap wafer 210. The standoff 217 and the eutectic anchor 218 form a gap-control structure. Reference number 216 in FIG. 2d corresponds to reference number 206 in FIG. 2a.

The microelectromechanical component may comprise one or more eutectic anchors. A plurality of eutectic anchors may be substantially evenly distributed around the standoff. Alternatively, a single eutectic anchor may surround the standoff. The ratio of the surface area of the eutectic anchor to the surface area of the standoff in the xy-plane may be in the range [1:10-10:1] or [1:3-3:1].

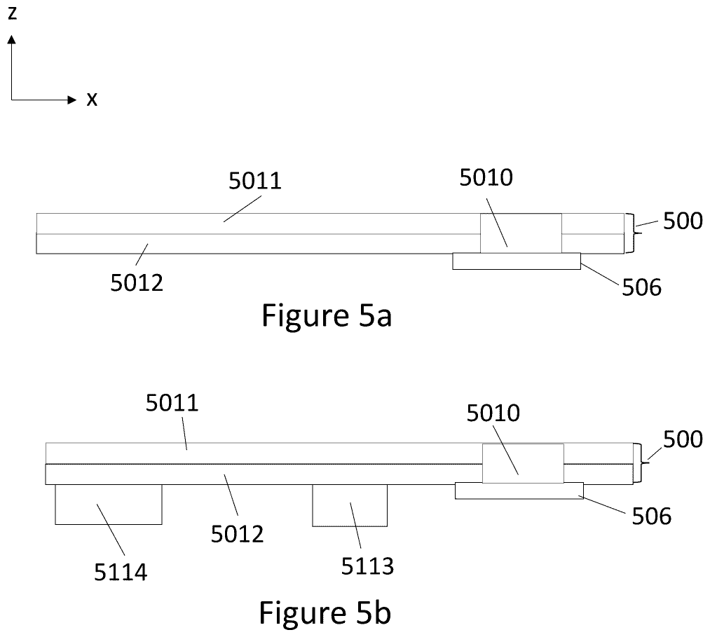

FIGS. 3a-3c illustrate different possible shapes and positions of eutectic anchors in a microelectromechanical component. FIG. 3a illustrates an example of a simplified top view of the structure wafer 301 in a microelectromechanical component. In this example, the microelectromechanical component comprises a single eutectic anchor 308 which is adjacent to the standoff 307. Reference numbers 304 and 305 in FIG. 3a correspond to reference numbers 204 and 205, respectively, in FIG. 2a. Reference number 309 in FIG. 3a corresponds to reference number 209 in FIG. 2b.

FIG. 3b illustrates another example of a simplified top view of the structure wafer in a microelectromechanical component. In this example, the microelectromechanical component comprises two eutectic anchors 318 which are adjacent to the standoff 317. The eutectic anchors 318 are located opposite to each other on different sides of the standoff 317. Reference numbers 311, 314 and 315 in FIG. 3b correspond to reference numbers 201, 204 and 205, respectively, in FIG. 2a. Reference number 319 in FIG. 3b corresponds to reference number 209 in FIG. 2b.

FIG. 3c illustrates another example of a simplified top view of the structure wafer in a microelectromechanical component. In this example, the microelectromechanical component comprises one eutectic anchor 328 surrounding the standoff 327. Reference numbers 321, 324 and 325 in FIG. 3c correspond to reference numbers 201, 204 and 205, respectively, in FIG. 2a. Reference number 329 in FIG. 3c corresponds to reference number 209 in FIG. 2b.

The cap wafer may comprise at least one electrically conductive via wherein the electrically conductive via extends along the z-axis through the cap wafer so that it meets the metal layer. The electrically conductive via may extend through at least a portion of the cap wafer thickness. Alternatively, the electrically conductive via may extend through the whole cap wafer thickness.

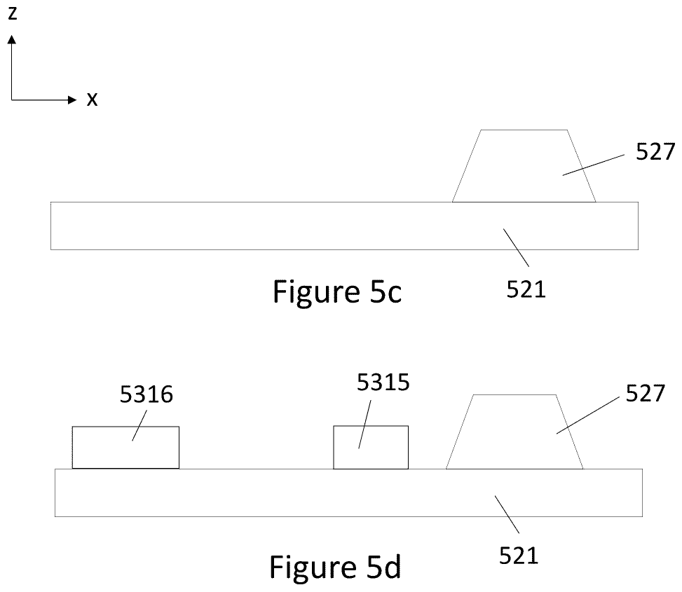

FIG. 4a illustrates a simplified example of a sectional view of a microelectromechanical component comprising a gap-control structure. The microelectromechanical component comprises a cap wafer 400 and a structure wafer 401 which are bonded together via a eutectic seal 409. In this example, the cap wafer 400 comprises an electrically conductive via 4010 which extends through the whole cap wafer thickness. The microelectromechanical component further comprises a metal layer 406, which is located at the bottom side of cap wafer in the cap wafer gap-control region. The metal layer 406 extends along the bottom surface of the cap wafer so that it meets the bottom side of the electrically conductive via 4010. The cap wafer may be made of an insulating material such as glass. The electrically conductive via may be a semiconducting via. Alternatively, the electrically conductive via may be a metal via. The metal layer 406 may be connected to an external electrical connection through the electrically conductive via 4010. Reference numbers 407 and 408 in FIG. 4a correspond to reference numbers 207 and 208, respectively, in FIG. 2b.

The cap wafer may comprise a semiconducting part and an insulating part, wherein the semiconducting part is located on top of the insulating part so that the bottom surface of the insulating part forms the bottom surface of the cap wafer. The cap wafer may further comprise at least one electrically conductive via. The electrically conductive via may extend along the z-axis from the bottom side of the semiconducting part to the bottom side of the insulating part so that the insulating part surrounds the sides of the electrically conductive via. The metal layer may extend along the bottom surface of the insulating part so that it meets the bottom side of the electrically conductive via.

Alternatively, the cap wafer may comprise a metal part and an insulating part, wherein the metal part is located on top of the insulating part so that the bottom surface of the insulating part forms the bottom surface of the cap wafer. The cap wafer may further comprise at least one electrically conductive via. The electrically conductive via may extend along the z-axis from the bottom side of the metal part to the bottom side of the insulating part so that the insulating part surrounds the sides of the electrically conductive via. The metal layer may extend along the bottom surface of the insulating part so that it meets the bottom side of the electrically conductive via

FIG. 4b illustrates another example of a sectional view of a microelectromechanical component with a gap-control structure. The microelectromechanical component comprises a cap wafer 410 and a structure wafer 411 which are bonded together via a eutectic seal 419. In this example, the cap wafer comprises a semiconducting part and an insulating part. The semiconducting part 4111 is located on top of the insulating part 4112 so that the bottom surface of the insulating part forms the bottom surface of the cap wafer. The cap wafer 410 further comprises an electrically conductive via 4110 which extend along the z-axis from the bottom side of the semiconducting part 4111 to the bottom side of the insulating part 4112 so that the insulating part surrounds the sides of the electrically conductive via 4110. The microelectromechanical component further comprises a metal layer 416, which is located at the bottom side of cap wafer in the cap wafer gap-control region. The metal layer 416 extends along the bottom surface of the insulating part so that it meets the bottom side of the electrically conductive via 4110. The electrically conductive via may be a semiconducting via. Alternatively, the electrically conductive via may be a metal via. The metal layer 416 may be connected to an external electrical connection through the electrically conductive via 4110. The structure wafer 411 comprises a standoff 417 which is located in the structure wafer gap-control region. The standoff 417 protrudes in the z-direction outward from the top surface of the structure wafer 411 so that it meets the metal layer 416. The standoff 417 and the metal layer 416 may serve as a good ohmic press-on contact inside the element. The standoff 417 and the adjacent eutectic anchor 418 serve as an accurate gap-height control structure as the eutectic anchor 418 contributes to securing a stable contact between the standoff 417 and the metal layer 416. In addition, the eutectic anchor adds mechanical strength to the structure making it robust to lifetime testing.

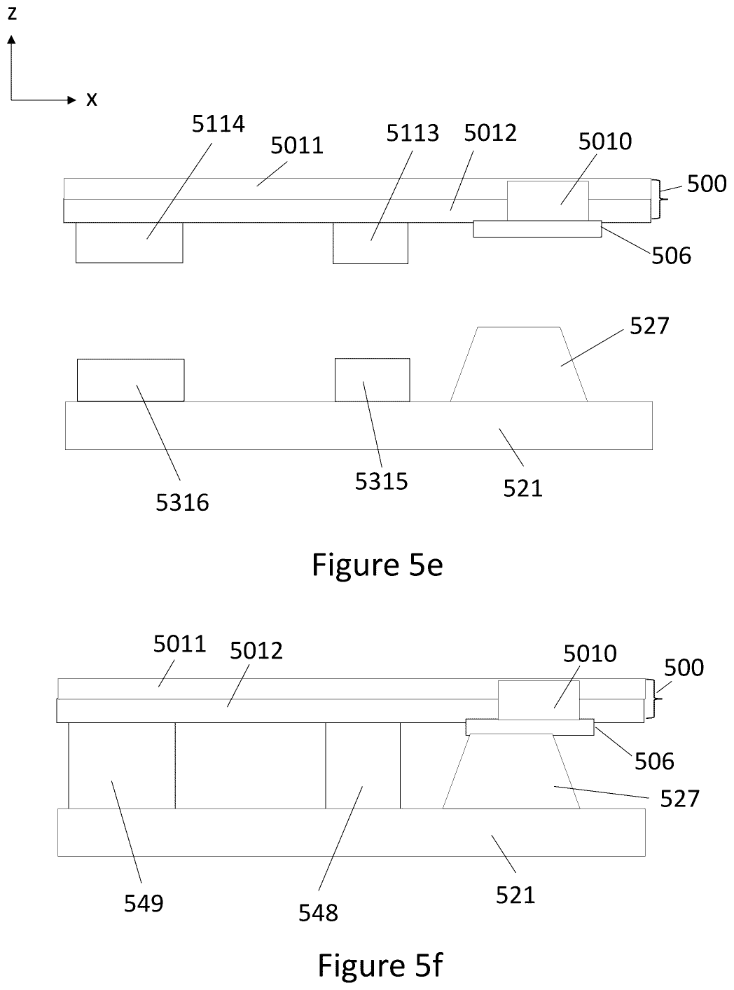

FIGS. 5a-5f provide a simplified illustration of an example method for manufacturing a microelectromechanical component with a gap-control structure. The microelectromechanical component comprises a cap wafer and a structure wafer. The cap wafer has a top surface and a bottom surface. The top surface of the cap wafer defines a horizontal xy-plane and a vertical z-direction which is perpendicular to the xy-plane. The cap wafer comprises a cap wafer sealing region and a cap wafer gap-control region, and the cap wafer sealing region surrounds the cap wafer gap-control region. The structure wafer has a top surface and a bottom surface. The top surface of the structure wafer is parallel to the xy-plane. The structure wafer comprises a structure wafer sealing region and a structure wafer gap-control region, and the structure wafer sealing region surrounds the structure wafer gap-control region.

The method comprises: (1) forming a first metal layer on the bottom surface of the cap wafer in the cap wafer gap-control region, (2) forming a second metal layer on the bottom surface of the cap wafer next to the first metal layer in the cap wafer gap-control region, (3) forming a standoff in the structure wafer gap-control region so that the standoff protrudes outward from the top surface of the structure wafer and extends in the z-direction, (4) forming a third metal layer on the top surface of the structure wafer next to the standoff in the structure wafer gap-control region, (5) placing the cap wafer on top of the structure wafer so that the first metal layer is aligned with the standoff along the z-axis and the second metal layer is aligned with the third metal layer along the z-axis, (6) bonding the cap wafer sealing region and the structure wafer sealing region together so that the top surface of the standoff is connected to the first metal layer, and the second metal layer and the third metal layer form a eutectic anchor. The components described above may include any structural feature which is included in the following presentation of manufacturing method.

The structure wafer may be a semiconductor device layer which has been attached to a support layer. The device layer may be a layer of silicon. The device layer and the support layer may for example be parts of a silicon-on-insulator (SOI) substrate where MEMS elements can be formed by patterning the top silicon layer (the device layer).

The method for manufacturing a microelectromechanical component with a gap-control structure may comprise the step of forming a dielectric/insulating layer on the top surface of the structure wafer before forming the third metal layer. The dielectric/insulating layer has the advantage of preventing possible chemical reactions between the eutectic anchor and the structure wafer. The dielectric/insulating layer may be an oxide or a nitride such as SiO₂, ZrO₂, HfO₂, Ta₂O₃, or SiNx. This option may apply to any aspect in this disclosure.

The cap wafer may be an insulating wafer such as a glass layer, or a wafer comprising semiconducting parts and insulating parts, or a wafer comprising metal parts and insulating parts. The cap wafer may for example comprise a semiconducting part and an insulating part, wherein the semiconducting part is located on top of the insulating part so that the bottom surface of the insulating part forms the bottom surface of the cap wafer. The cap wafer may further comprise at least one electrically conductive via. The electrically conductive via may extend along the z-axis from the bottom side of the semiconducting part to the bottom side of the insulating part so that the insulating part surrounds the sides of the electrically conductive via. The first metal layer may extend along the bottom surface of the insulating part so that it meets the bottom side of the electrically conductive via.

FIG. 5a illustrates one of the first steps of the example method for manufacturing a microelectromechanical component with a gap-control structure. In this example, the cap wafer 500 comprises a semiconducting part 5011 and an insulating part 5012. The semiconducting part 5011 is located on top of the insulating part 5012 so that the bottom surface of the insulating part forms the bottom surface of the cap wafer 500. The cap wafer 500 further comprises an electrically conductive via 5010 which extend along the z-axis from the bottom side of the semiconducting part 5011 to the bottom side of the insulating part 5012 so that the insulating part surrounds the sides of the electrically conductive via 5010. This step comprises forming a first metal layer 506 on the bottom surface of the cap wafer 500 in the cap wafer gap-control region so that the first metal layer 506 meets the bottom of the electrically conductive via 5010. The first metal layer may be made of a variety of metals that include but are not limited to Al, Cu, Ag, Au, Pt, Pd, Mo or metal alloys. The first metal layer may be formed by a variety of deposition methods such as sputtering, chemical vapor deposition, molecular beam epitaxy, electron beam physical vapor evaporation, or laser metal deposition. The thickness of the first metal layer 506 may be in the range [0.1-1.0] μm, or [0.1-0.5] μm, or [0.3-0.7] μm. The electrically conductive via may be a semiconducting via. Alternatively, the electrically conductive via may be a metal via.

FIG. 5b illustrates another step in the method for manufacturing a microelectromechanical component with a gap-control structure. In this step, a second metal layer 5113 is formed on the bottom surface of the cap wafer in the cap wafer gap-control region next to the first metal layer 506. A first additional metal layer 5114 may simultaneously be formed in the cap wafer sealing region. The second metal layer 5113 and the first additional metal layer 5114 may be made of the same metal. Alternatively, the second metal layer 5113 and the first additional metal layer 5114 may be made of different metals.

FIG. 5c illustrates another step in the method for manufacturing a microelectromechanical component with a gap-control structure. In this step, a standoff 527 is formed in the structure wafer gap-control region so that the standoff protrudes outward from the top surface of the structure wafer 521 and extends in the z-direction. The standoff 527 may be formed by semiconductor microfabrication techniques such as LOCOS process, wet etching process or dry etching process.

FIG. 5d illustrates a further step in the method for manufacturing a microelectromechanical component with a gap-control structure. In this step, a third metal layer 5315 is formed on the top surface of the structure wafer 521 in the structure wafer gap-control region next to the standoff 527. A second additional metal layer 5316 may simultaneously be formed in the structure wafer sealing region. The third metal layer 5315 and the second additional metal layer 5316 may be made of the same metal. Alternatively, the third metal layer 5315 and the second additional metal layer 5316 may be made of different metals.

The second metal layer 5113 and the third metal layer 5315 may be made of any metals that form a eutectic alloy at a corresponding eutectic temperature. The first additional metal layer 5114 and the second additional metal layer 5316 may be made of any metals that form a eutectic alloy at a corresponding eutectic temperature. Such metals may include, but are not limited to, Au—Sn, Au—In or Cu—Sn. These options may apply to any aspect in this disclosure.

FIG. 5e illustrates the step of the method for manufacturing a microelectromechanical component where the cap wafer 500 is placed on top of the structure wafer 521 so that the first metal layer 506 is aligned with the standoff 527 along the z-axis and the second metal layer 5113 is aligned with the third metal layer 5315 along the z-axis.

FIG. 5f illustrates the final step of the example method for manufacturing a microelectromechanical component with a gap-control structure. In this step, the cap wafer 500 and structure wafer 521 are pressed together at a specific eutectic temperature. Consequently, the cap wafer sealing region and the structure wafer sealing region are bonded together through the eutectic seal 549 formed by the chemical reaction between the first additional metal layer 5114 and the second additional metal layer 5316. Simultaneously, the standoff 527 comes into contact with the first metal layer 506 and a eutectic anchor 548 is formed by the chemical reaction between the second metal layer 5113 and the third metal layer 5315. The eutectic temperature may be in the range [300-500]° C., [400-450]° C., or [420-450]° C.

The standoff 527 and the first metal layer 506 may serve as a good ohmic press-on contact inside the MEMS element after the eutectic bonding. The standoff 527 and the adjacent eutectic anchor 548 form an accurate gap-height control structure as the eutectic anchor 548 contributes to securing a stable contact between the standoff 527 and the first metal layer 506.

The method for manufacturing a microelectromechanical component with a gap-control structure may further comprise the steps of forming a metalloid layer on top of the third metal layer before placing the cap wafer on top of the structure wafer, then bonding the cap wafer and the structure wafer together so that the second metal layer, the third metal layer and the metalloid layer form a eutectic anchor.

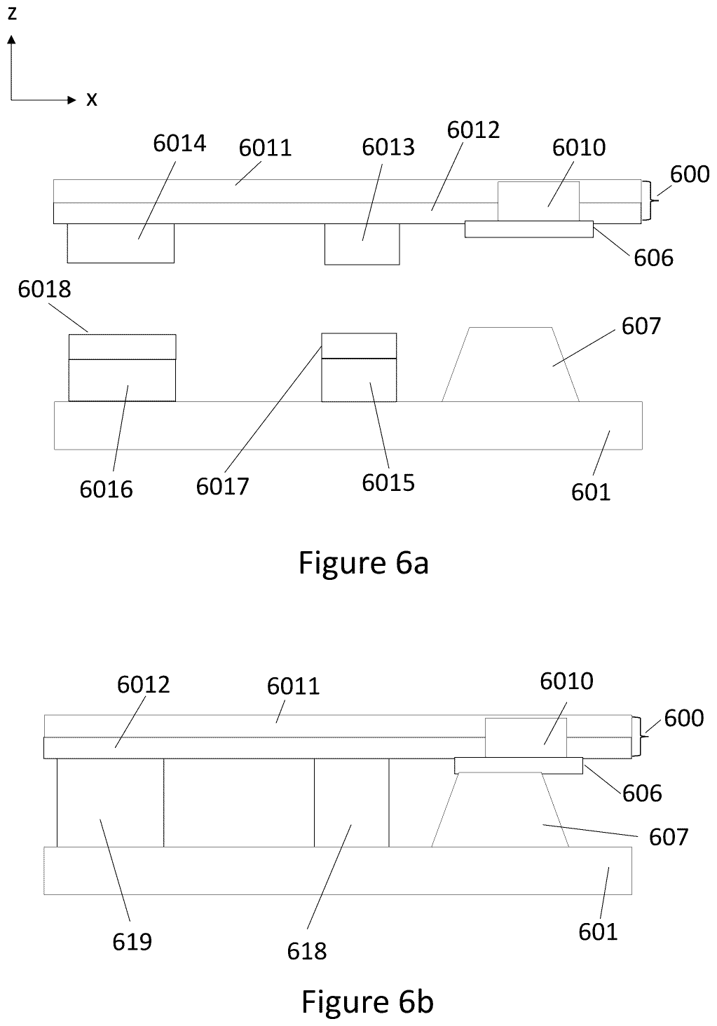

FIG. 6a illustrates an example of a microelectromechanical component before the cap wafer and the structure wafer are bonded together. In this example, a metalloid layer 6017 is formed on top of the third metal layer 6015 before the eutectic bonding step. Simultaneously, an additional metalloid layer 6018 may be formed on top of the second additional metal layer 6016 before the eutectic bonding step. In such structure, the second metal layer 6013 may be an Al layer, the third metal layer 6015 may be a Ti layer, and the metalloid layer 6017 may be a Ge layer. Reference numbers, 600, 601, 606, 607, 6010, 6011, 6012 and 6014 in FIG. 6a correspond to reference numbers 500, 521, 506, 527, 5010, 5011, 5012 and 5114, respectively, in FIG. 5e.

FIG. 6b illustrates the electromechanical component shown in FIG. 6a after the eutectic bonding of the cap wafer 600 and the structure wafer 601 together at eutectic temperature. The cap wafer sealing region and the structure wafer sealing region are bonded together through the eutectic seal 619 formed by the chemical reaction between of the first additional metal layer 6014, the second additional metal layer 6016, and the additional metalloid layer 6018. Simultaneously, the standoff 607 meets the first metal layer 606 and a eutectic anchor 618 is formed by the chemical reaction between the second metal layer 6013, the third metal layer 6015, and the metalloid layer 6017. Reference numbers 6010, 6011 and 6012 in FIG. 6b correspond to reference numbers 5010, 5011 and 5012, respectively, in FIG. 5a.

Alternatively, the method for manufacturing a microelectromechanical component may further comprise the steps of forming a metalloid layer at the bottom of the second metal layer before placing the cap wafer on top of the structure wafer, then bonding the cap wafer and the structure wafer together so that the second metal layer, the third metal layer and the metalloid layer form a eutectic anchor.

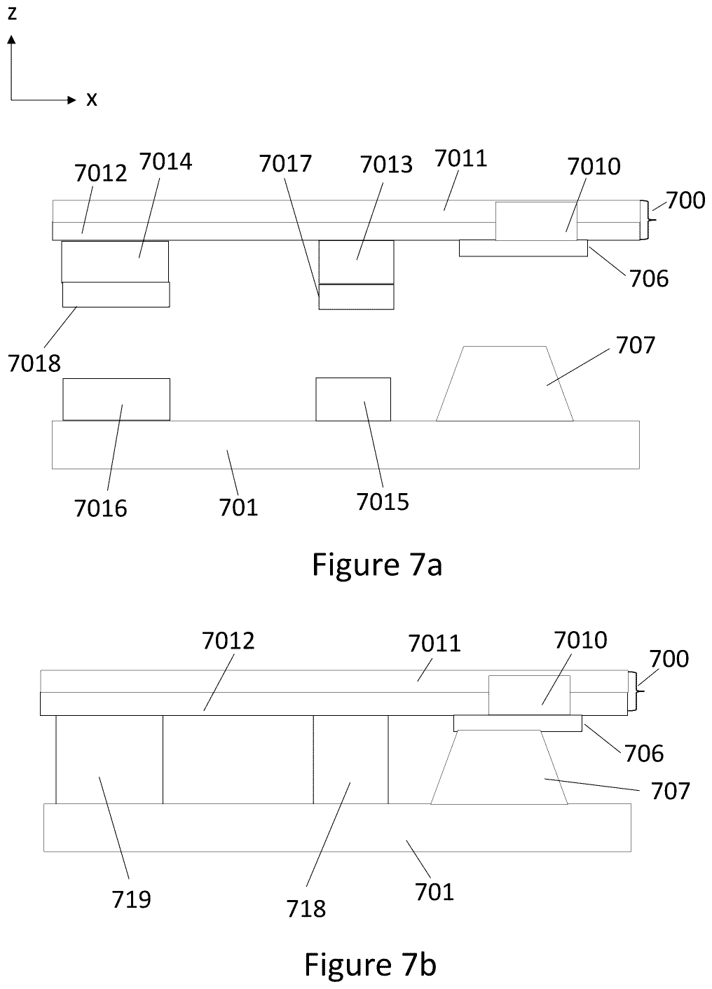

FIG. 7a illustrates another example of a microelectromechanical component before the cap wafer and the structure wafer are bonded together. In this example, a metalloid layer 7017 is formed at the bottom of the second metal layer 7013 before the eutectic bonding step. Simultaneously, an additional metalloid layer 7018 may be formed at the bottom of the first additional metal layer 7014 before the eutectic bonding step. Reference numbers 700, 701, 706, 707, 7010, 7011, 7012, 7015 and 7016 in FIG. 7a correspond to reference numbers 500, 521, 506, 527, 5010, 5011, 5012, 5315 and 5316, respectively, in FIG. 5e.

FIG. 7b illustrates the electromechanical component shown in FIG. 7a after the eutectic bonding of the cap wafer 700 and the structure wafer 701 together at eutectic temperature. The cap wafer sealing region and the structure wafer sealing region are bonded together through the eutectic seal 719 formed by the chemical reaction between of the first additional metal layer 7014, the second additional metal layer 7016, and the additional metalloid layer 7018. Simultaneously, the standoff 707 meets the first metal layer 706 and a eutectic anchor 718 is formed by the chemical reaction between the second metal layer 7013, the third metal layer 7015, and the metalloid layer 7017. The second metal layer may be a Ti layer, the third metal layer may be an Al layer, and the metalloid layer may be a Ge layer. Reference numbers 7010, 7011 and 7012 in FIG. 7b correspond to reference numbers 5010, 5011 and 5012, respectively, in FIG. 5a.

Alternatively, the eutectic anchor may be made of a eutectic alloy comprising only one metal layer, for example, and one metalloid layer such as an Al—Ge eutectic alloy. In such aspects, the metalloid layer may be formed either on the top surface of the structure wafer or on the bottom surface of the cap wafer. Similarly, the eutectic seal may be made of a eutectic alloy comprising only one metal layer, for example, and one metalloid layer.

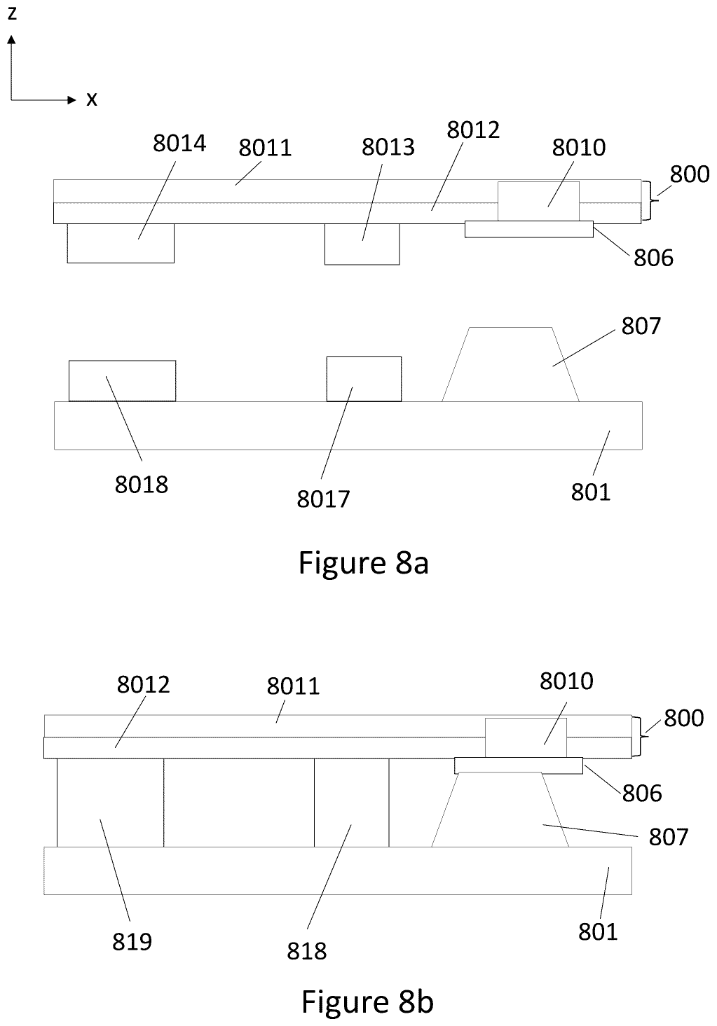

FIG. 8a illustrates a simplified example of a sectional view of a microelectromechanical component comprising a gap-control structure before and after bonding. In this example the metalloid layer 8017 is formed on the top surface of the structure wafer 801 next to the standoff 807 in the structure wafer gap-control region. An additional metalloid layer 8018 may simultaneously be formed on the top surface of the structure wafer in the structure wafer sealing region. Reference numbers 800, 806, 8010, 8011, 8012, 8013 and 8014 in FIG. 8a correspond to reference 500, 506, 5010, 5011, 5012, 5113 and 5114, respectively, in FIG. 5b.

FIG. 8b illustrates the electromechanical component shown in FIG. 8a after the eutectic bonding of the cap wafer 800 and the structure wafer 801 together at eutectic temperature. In this example, the cap wafer sealing region and the structure wafer sealing region are bonded together through the eutectic seal 819 formed by the chemical reaction between of the first additional metal layer 8014 and the additional metalloid layer 8018. Simultaneously, the standoff 807 comes into contact with the first metal layer 806 and a eutectic anchor 818 is formed by the chemical reaction between the second metal layer 8013 and the metalloid layer 8017. Reference numbers 8010, 8011 and 8012 in FIG. 8b correspond to reference numbers 5010, 5011 and 5012, respectively, in FIG. 5a.

In general, the description of the aspects disclosed should be considered as being illustrative in all respects and not being restrictive. The scope of the present disclosure is shown by the claims rather than by the above description and is intended to include meanings equivalent to the claims and all changes in the scope. While preferred aspects of the invention have been described above, it is to be understood that variations and modifications will be apparent to those skilled in the art without departing from the scope and spirit of the invention.

1. A microelectromechanical component comprising:
a cap wafer including a cap wafer sealing region and a cap wafer gap-control region, the cap wafer sealing region surrounding the cap wafer gap-control region; and
a structure wafer including a structure wafer sealing region and a structure wafer gap-control region, the structure wafer sealing region surrounding the structure wafer gap-control region;
wherein the cap wafer has a top surface and a bottom surface, the top surface of the cap wafer defining a horizontal xy-plane and a vertical z-direction that is perpendicular to the xy-plane,
wherein the structure wafer has a top surface and a bottom surface, and the top surface of the structure wafer parallel to the xy-plane,
wherein the cap wafer and the structure wafer are bonded to each other by a eutectic seal that connects the cap wafer sealing region to the structure wafer sealing region so that the cap wafer gap-control region is aligned with the structure wafer gap-control region along a z-axis, and
wherein the microelectromechanical component further includes a metal layer located at the bottom surface of the cap wafer in the cap wafer gap-control region, and the structure wafer further comprises a standoff in the structure wafer gap-control region, wherein the standoff protrudes outward from the top surface of the structure wafer and extends along the z-direction so that it meets the metal layer.

2. The microelectromechanical component according to claim 1, wherein the microelectromechanical component further includes a eutectic anchor attached to the top surface of the structure wafer in the structure wafer gap-control region next to the standoff.

3. The microelectromechanical component according to claim 2, wherein the eutectic anchor extends along the z-direction from the top surface of the structure wafer to the bottom surface of the cap wafer.

4. The microelectromechanical component according to claim 3, wherein the eutectic anchor comprises an alloy comprising a metalloid.

5. The microelectromechanical component according to claim 4, wherein the eutectic anchor comprises Ge, Al, and Ti.

6. The microelectromechanical component according to claim 4, wherein the eutectic anchor comprises Ge and Al.

7. The microelectromechanical component according to claim 1, wherein the cap wafer comprises an electrically conductive via that extends along the z-axis through the cap wafer to meet the metal layer.

8. The microelectromechanical component according to claim 7, wherein the electrically conductive via is a semiconducting via.

9. The microelectromechanical component according to claim 7, wherein the electrically conductive via is a metal via.

10. The microelectromechanical component according to claim 3, wherein the cap wafer comprises an electrically conductive via that extends along the z-axis through the cap wafer to meet the metal layer.

11. A method for manufacturing a microelectromechanical component with a gap-control structure, the method comprising:
forming a first metal layer on a bottom surface of a cap wafer in a cap wafer gap-control region;
forming a second metal layer on the bottom surface of the cap wafer next to the first metal layer in the cap wafer gap-control region;
forming a standoff in the structure wafer gap-control region so that the standoff protrudes outward from a top surface of the structure wafer and extends in a z-direction;
forming a third metal layer on the top surface of the structure wafer next to the standoff in the structure wafer gap-control region;
placing the cap wafer on top of the structure wafer so that the first metal layer is aligned with the standoff along a z-axis and the second metal layer is aligned with the third metal layer along the z-axis; and
bonding a cap wafer sealing region and the structure wafer sealing region together so that the top surface of the standoff is connected to the first metal layer, and the second metal layer and the third metal layer form a eutectic anchor.

12. The method for manufacturing the microelectromechanical component according to claim 11, wherein the microelectromechanical component comprises a cap wafer and a structure wafer, and wherein the cap wafer has the top surface and the bottom surface, and the top surface of the cap wafer defines a horizontal xy-plane and a vertical z-direction which is perpendicular to the xy-plane.

13. The method for manufacturing the microelectromechanical component according to claim 12, wherein the cap wafer comprises the cap wafer sealing region and a cap wafer gap-control region, and the cap wafer sealing region surrounding the cap wafer gap-control region, wherein the structure wafer has a top surface and a bottom surface, and the top surface of the structure wafer is parallel to the xy-plane.

14. The method for manufacturing the microelectromechanical component according to claim 13, wherein the structure wafer comprises a structure wafer sealing region and a structure wafer gap-control region, and the structure wafer sealing region surrounds the structure wafer gap-control region.

15. The method for manufacturing the microelectromechanical component according to claim 11, further comprising forming a metalloid layer on top of the third metal layer before placing the cap wafer on top of the structure wafer, then bonding the cap wafer and the structure wafer together so that the second metal layer, the metalloid layer, and the third metal layer form a eutectic anchor.

16. The method for manufacturing the microelectromechanical component according to claim 15, wherein the second metal layer is an Al layer, the third metal layer is a Ti layer, and the metalloid layer is a Ge layer.

17. The method for manufacturing the microelectromechanical component according to claim 11, further comprising forming a metalloid layer at the bottom of the second metal layer before placing the cap wafer on top of the structure wafer, then bonding the cap wafer and the structure wafer together so that the second metal layer, the metalloid layer, and the third metal layer form a eutectic anchor.

18. The method for manufacturing a microelectromechanical component according to claim 17, wherein the second metal layer is a Ti layer, the third metal layer is an Al layer, and the metalloid layer is a Ge layer.

19. The method for manufacturing a microelectromechanical component according to claim 13, wherein the cap wafer comprises a semiconducting part and an insulating part, wherein the semiconducting part is located on top of the insulating part so that the bottom surface of the insulating part forms the bottom surface of the cap wafer, and wherein the cap wafer further comprises an electrically conductive via.

20. The method for manufacturing the microelectromechanical component according to claim 19, wherein the electrically conductive via extends along the z-axis from a bottom side of the semiconducting part to the bottom side of the insulating part so that the insulating part surrounds the sides of the electrically conductive via, and wherein the first metal layer extends along the bottom surface of the insulating part to meet the bottom side of the electrically conductive via.
